(19) United States
(12) Patent Application Publication
(10) Pub. No.: US 2004/0013951 A1
(43) Pub. Date: Jan. 22, 2004

(54) Method for machining translucent material by laser beam and machined translucent material

(76) Inventor: Jun Wang, Tokyo (JP)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/415,148

(22) PCT Filed: Apr. 2, 2002
(86) PCT No.: PCT/JP02/03302

(30) Foreign Application Priority Data
Apr. 2, 2001 (JP) 2000-103369

(51) Int. Cl. G03F 1/00; B29C 35/08; G03F 7/20; B23K 26/18; B23K 26/36; C03B 37/018; C03B 37/022

(52) U.S. Cl. 430/5; 264/400; 219/121.69; 219/121.71; 65/386; 65/392; 430/321; 430/323

(57) ABSTRACT

A transparent material is processed by applying a laser beam through a light-absorbing layer to a processed surface of the transparent material to form a hole or a groove in the processed surface. The hole or groove is formed in the surface by applying the beam along an edge of the light absorbing layer, which has a thickness greater than the beam penetration depth.

### TECHNICAL FIELD

The present invention relates to a method for processing with a laser beam a transparent material with low light absorption, such as glass and transparent plastic, and a transparent material which is processed with the laser beam.

### BACKGROUND ART

As a method for processing a transparent material with low light absorption, such as glass and transparent plastic, by applying a laser beam, the following methods (1) to (3) have been proposed.

(1) A back surface of a transparent material is in contact with a solution containing metal ions, and a laser beam is applied to a front surface of the transparent material, thereby forming a hole in the back surface of the transparent material, which is in contact with the solution containing the metal ions.

(2) A thin metallic absorbing layer or organic absorbing layer is provided on a surface of an optical crystal containing metal ions, and a laser beam is applied to the absorbing layer, thereby generating an altered layer with a higher laser beam absorptivity on the surface of the optical crystal, and processing the optical crystal by applying the laser beam to the altered layer. Alternatively, a solution containing metal ions or a color ink is applied to a surface of a glass containing an impurity, and a laser beam is applied to the solution containing the metal ions or the color ink, thereby generating an altered layer with a higher laser beam absorptivity on the surface of the glass, and processing the glass by applying the laser beam to the altered layer.

(3) A light-absorbing layer is provided on a surface of a transparent material, and a laser beam is applied via a lens to be focused on a boundary between the light-absorbing layer and the transparent material, thereby engraving the transparent material (Japanese Patent Publication No. H9-192857).

However, according to the method (1) described above, the laser beam is applied to the front surface of the transparent material, and the back surface of the transparent material is processed with the laser beam passing through the transparent material. Therefore, it is difficult to control the processing itself, and the processing shape is limited.

Furthermore, according to the methods (2) and (3) described above, the altered layer having the higher laser beam absorptivity is generated on the surface of the transparent material with the laser beam, and then the laser beam is applied to the altered layer to process the transparent material. Therefore, a material on which the altered layer cannot be generated, such as a quartz glass, cannot be used as the material to be processed. Besides, these methods require a high energy laser beam, and thus, there is the possibility that the applied laser beam may cause a crack in the transparent material depending on the property or thickness of the transparent material.

The present invention has been devised in view of such circumstances. Primarily aims of the invention are to provide a method for precisely processing a transparent material with a low energy laser beam as desired without regard to the kind of the laser beam or the property of the transparent material, and to provide a product obtained by processing a transparent material with the laser beam.

### DISCLOSURE OF THE INVENTION

A processing method of the present invention is a method for processing a transparent material with a laser beam, in which the laser beam is applied through a light-absorbing layer to a surface to be processed of the transparent material to form a hole or a groove in the surface to be processed, wherein a thickness of the light-absorbing layer is more than a penetration depth of the laser beam, which is expressed by 1/α, providing that an extinction coefficient of the light-absorbing layer for the laser beam is α. According to the processing method, without regard to the kind of the laser beam or the property of the transparent material, the transparent material can be processed precisely with a low energy laser beam as desired.

A processed transparent material of the present invention is a product obtained by processing a transparent material by applying a laser beam to a surface to be processed of the transparent material through a light-absorbing layer, wherein a transmittance of a processed part is 5% or less of that of a non-processed part. According to the product can excellently serve as an optical element for controlling transmission of a laser beam.

### BRIEFLY DESCRIBE OF THE DRAWINGS

FIGS. 1(A) and 1(B) are views for explaining a illustrate a first processing method;

FIGS. 2(A) and 2(B) are views for explaining a second processing method;

FIGS. 3(A) and 3(B) are views for explaining a third processing method;

FIGS. 4(A) and 4(B) are views for explaining a variation of the third processing method;

FIGS. 5(A) and 5(B) are views for explaining a fourth processing method;

FIGS. 6(A) and 6(B) are views for explaining a fifth processing method;

FIGS. 7(A) and 7(B) are views for explaining a sixth processing method;

FIGS. 8(A) and 8(B) are views for explaining a seventh processing method; and

FIGS. 9(A) and 9(B) are views for showing a light-absorbing layer comprising a plurality of parts with different extinction coefficients.

### BEST MODE FOR CARRYING OUT THE INVENTION

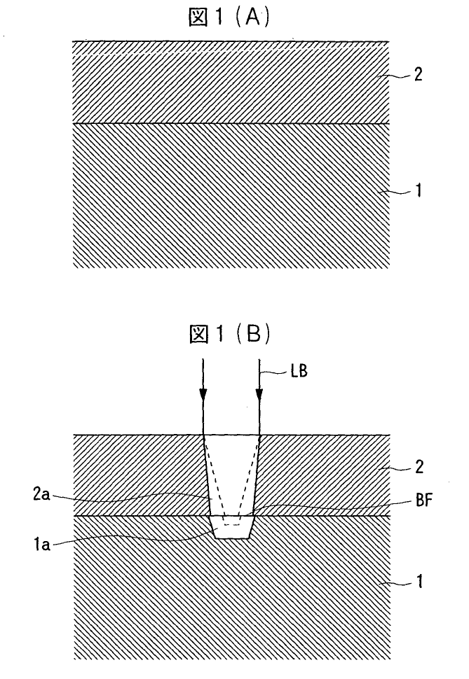

FIGS. 1(A) and 1(B) illustrate a first processing method. In this drawing, reference numeral 1 denotes a transparent material to be processed, reference numeral 2 denotes a light-absorbing layer provided on a surface to be processed of the transparent material 1, and reference character LB denotes a laser beam applied to the light-absorbing layer 2.

The transparent material 1 is a material that absorbs little laser beam LB, such as glass including quartz glass, borosilicate glass, aluminosilicate glass, soda lime glass and no-alkali glass; a plastic including polycarbonate, acrylic plastic and fluoroplastic; and a crystal including quartz, CaF₂, sapphire, SiC, GaN and diamond. In addition, the material that absorbs little laser beam LB includes a fluoroplastic, glass or the like that is opaque due to light scattering.

The light-absorbing layer 2 is a layer made of a material having a predetermined extinction coefficient a for the laser beam LB. For example, it may be a layer made of plastic selected among from thermoplastics including polymethyl methacrylate (PMMA), polyethylene (PE) and polyimide (PI); a layer made of ceramics containing at least one selected among from SiO₂, Al₂O₃, CaO, Na₂O, B₂O₃, SiC, Si₃N₄, B₄C, TiO₂, BeO, AlN, MgO, BaTiO₃, SrTiO₃, ZnO, SnO₂, CrO₂, Fe₂O₃ and the like; a layer of a slurry containing a powdered ceramics selected among from these ceramics; a layer obtained by drying the slurry layer; a layer made of metal containing at least one selected among from Au, Ag, Pt, Pd, Ni, Cu, Fe, Al and the like; a layer of a paste containing a powdered metal selected among from these metals; a layer obtained by drying the paste layer; a layer made of carbon; a layer of a paste containing a powdered carbon; or a layer obtained by drying the paste layer.

If the light-absorbing layer 2 is to be formed from the plastic as described above, there may be used a method of attaching the plastic previously shaped into a film onto the surface to be processed of the transparent material 1; or a method of applying the plastic previously fluidized by heating to the surface to be processed of the transparent material 1 and curing the plastic to form the layer.

Alternatively, if the light-absorbing layer 2 is to be formed from the ceramics as described above, there may be used a method of attaching the ceramics previously shaped into a sheet onto the surface to be processed of the transparent material 1; or a method of applying a slurry to the surface to be processed of the transparent material 1 and sintering the slurry to form the layer, the slurry containing a powdered ceramics, an organic binder and an organic solvent as essential ingredients and containing a disperser or plasticizer as required. The organic binder may be at least one selected among from acrylic plastic, phenol plastic, alkyd plastic, rosin ester and various kinds of cellulose, and the organic solvent may be at least one selected among from alcohol-based solvents, hydrocarbon-based solvents, ether solvents and ester solvents.

If the light-absorbing layer 2 is to be formed of the layer of the slurry containing the powdered ceramics as described above, there may be used a method of applying the slurry to the surface to be processed of the transparent material 1 to form the layer. If the light-absorbing layer 2 is to be formed of the layer obtained by drying the layer of the slurry containing the powdered ceramics as described above, there may be used a method of applying the slurry to the surface to be processed of the transparent material 1 and drying the applied layer; or a method of attaching to the surface to be processed of the transparent material 1 a sheet of the slurry applied to a plastic film and dried.

If the light-absorbing layer 2 is to be formed from the metal as described above, there may be used a method of attaching the metal previously shaped into a film onto the surface to be processed of the transparent material 1; a method of directly forming the metal layer on the surface to be processed of the transparent material 1 by a thin film forming method, such as vapor deposition and sputtering; or a method of applying a paste to the surface to be processed of the transparent material 1 and sintering the paste to form the layer, the paste containing a powdered metal, the organic above-mentioned binder and the above-mentioned organic solvent as essential ingredients and containing an additive as appropriate.

If the light-absorbing layer 2 is to be formed of the layer of the paste containing the powdered metal as described above, there may be used a method of applying the paste to the surface to be processed of the transparent material 1 to form the layer. If the light-absorbing layer 2 is to be formed of the layer obtained by drying the layer of the paste containing the powdered metal as described above, there may be used a method of applying the paste to the surface to be processed of the transparent material 1 and drying the applied layer; or a method of attaching to the surface to be processed of the transparent material 1 a sheet of the paste applied to a plastic film and dried.

If the light-absorbing layer 2 is to be formed from the carbon as described above, there may be used a method of attaching the carbon previously shaped into a film onto the surface to be processed of the transparent material 1; a method of directly forming the carbon layer on the surface to be processed of the transparent material 1 by a thin film forming method, such as vapor deposition and sputtering; or a method of applying a paste to the surface to be processed of the transparent material 1 and sintering the paste to form the layer, the paste containing a powdered carbon, the organic above-mentioned binder and the above-mentioned organic solvent as essential ingredients and containing an additive as appropriate.

If the light-absorbing layer 2 is to be formed of the layer of the paste containing the powdered carbon as described above, there may be used a method of applying the paste to the surface to be processed of the transparent material 1 to form the layer. If the light-absorbing layer 2 is to be formed of the layer obtained by drying the layer of the paste containing the powdered carbon as described above, there may be used a method of applying the paste to the surface to be processed of the transparent material 1 and drying the applied layer; or a method of attaching to the surface to be processed of the transparent material 1 a sheet of the paste applied to a plastic film and dried.

The light-absorbing layer 2 may contain an extinction coefficient regulator for regulating the extinction coefficient α. For example, it may contain at least one of pigments such as an inorganic pigment, powdered metals such as copper, and a carbon powder.

The laser beam LB may be emitted from a gas laser, such as a He-Ne laser, an Ar-ion laser, a CO₂ laser and an excimer laser; a solid state laser, such as a YAG laser; or semiconductor laser. The laser beam is applied to the light-absorbing layer 2 through an optical system, not shown.

Processing of the transparent material 1 with the laser beam LB is carried out by irradiating the surface to be processed of the transparent material 1 with the laser beam LB through the light-absorbing layer 2 as shown in FIG. 1(B) in a state where the light-absorbing layer 2 is in contact with the surface to be processed of the transparent material 1 as shown in FIG. 1(A).

As a method of applying the laser beam LB, there may be adopted a method of applying a pulsed laser beam LB of a predetermined energy (power×application duration) intermittently a plurality of times, or a method of applying a laser beam LB of a predetermined power continuously for a predetermined time.

In the case where the pulsed laser beam LB of a predetermined energy is applied intermittently a plurality of times to the surface to be processed of the transparent material 1 through the light-absorbing layer 2, with the repeated applications of the laser beam LB, a hole formed in the light-absorbing layer 2 is gradually increased in depth to become a through hole 2a as shown by a broken line in FIG. 1(B), and a lower end diameter of the through hole 2a is gradually increased. During the gradual increase of the depth of the formed hole and the lower end diameter of the through hole 2a, the energy absorbed in the light-absorbing layer 2 is converted into heat. The heat produced at the interface BF between the transparent layer 1 and the light-absorbing layer 2 allows a hole to be formed in the surface to be processed of the transparent material 1, and the hole 1a is gradually increased in area and depth. Once the through hole 2a is formed in the light-absorbing layer 2, a part of the laser beam LB is directly applied to the surface to be processed of the transparent material 1 through the through hole 2a. However, processing of the transparent material 1 mainly relies on the heat produced at the interface BF between the transparent material 1 and the light-absorbing layer 2, and the directly applied laser beam LB is used for the processing only secondarily.

On the other hand, in the case where the laser beam LB of a predetermined power is applied continuously for a predetermined time to the surface to be processed of the transparent material 1 through the light-absorbing layer 2, with the lapse of time of application of the laser beam LB, a hole formed in the light-absorbing layer 2 is gradually increased in depth to become a through hole 2a as shown by a broken line in FIG. 1(B), and a lower end diameter of the through hole 2a is gradually increased. During the gradual increase of the depth of the formed hole and the lower end diameter of the through hole 2a, the energy absorbed in the light-absorbing layer 2 is converted into heat. The heat produced at the interface BF between the transparent layer 1 and the light-absorbing layer allows a hole to be formed in the surface to be processed of the transparent material 1, and the hole 1a is gradually increased in area and depth. Once the through hole 2a is formed in the light-absorbing layer 2, part of the laser beam LB is directly applied to the surface to be processed of the transparent material 1 through the through hole 2a. However, processing of the transparent material 1 mainly relies on the heat produced at the interface BF between the transparent material 1 and the light-absorbing layer 2, and the directly applied laser beam LB is used for the processing only secondarily.

For both the former and latter methods of applying the laser beam, by changing a point to which the laser beam LB is applied in a predetermined path, any groove, which is a series of holes 1a, can be formed in the surface to be processed of the transparent material 1 in the shape of the application path. For example, a linear groove, a meandering groove, or an annular groove can be formed.

In many cases, the hole 1a or the groove has a cross section in the shape of a trapezoid with an upper side width being longer than a lower side width or a shape approximating thereto, as shown in FIG. 1(B). However, depending on the energy of the applied laser beam LB or the property of the light-absorbing layer 2 or the transparent material 1, the hole 1a or the groove may have a cross section in the form of a semi-circle, U-shape or a shape approximating thereto, or V-shape or a shape approximating thereto.

The light-absorbing layer 2 serves to produce heat for processing at the interface BF between the transparent material 1 and the light-absorbing layer 2 by converting the energy of the applied laser beam LB into heat. In order to process the transparent material with a low energy laser beam as desired, it is required to efficiently produce heat at the interface BF between the transparent material 1 and the light-absorbing layer 2. To this end, the thickness t of the light-absorbing layer 2 is appropriately set depending on the kind of the laser beam used for the processing. Specifically, if the extinction coefficient of the light-absorbing layer 2 for the laser beam LB is α, the thickness t of the light-absorbing layer 2 is set to be larger than a penetration depth of the laser beam, expressed by 1/α. Here, the extinction coefficient α is defined by a formula of ∂I/∂x=−αI (where I is a light intensity and x is a distance). The extinction coefficient may be referred to as a light absorption coefficient or a light intensity attenuation coefficient.

For example, for polymethyl methacrylate that has an extinction coefficient α of 2000 cm⁻¹ for an ArF excimer laser beam having a wavelength γ of 193 nm, the penetration depth 1/α of the laser beam is 5 μm. Therefore, by setting the thickness t of the light-absorbing layer 2 made of polymethyl methacrylate at more than 5 μm, an intended processing can be accomplished precisely.

For polyimide that has an extinction coefficient a of 50 cm⁻¹ for a YAG laser beam having a wavelength γ of 1064 nm, the penetration depth 1/α of the laser beam is 200 μm. Therefore, by setting the thickness t of the light-absorbing layer 2 made of polyimide at more than 200 μm, an intended processing can be accomplished precisely.

For polyethylene containing carbon that has an extinction coefficient α of 500 cm⁻¹ for a YAG laser beam having a wavelength k of 1064 nm, the penetration depth 1/α of the laser beam is 20 μm. Therefore, by setting the thickness t of the light-absorbing layer 2 made of polyethylene containing carbon at more than 20 μm, an intended processing can be accomplished precisely.

Essentially, any intended processing can be accomplished if the thickness t of the light-absorbing layer 2 is more than the penetration depth of the laser beam LB expressed by 1/α, and therefore, there is no particular upper limit to the thickness t. However, since the energy loss before start of the processing is increased if the light-absorbing layer 2 is extremely thick, the thickness t of the light-absorbing layer 2 is desirably 100 times the penetration depth 1/α or less, and more desirably, 10 times the penetration depth or less, depending on the property of the material, processing condition or the like.

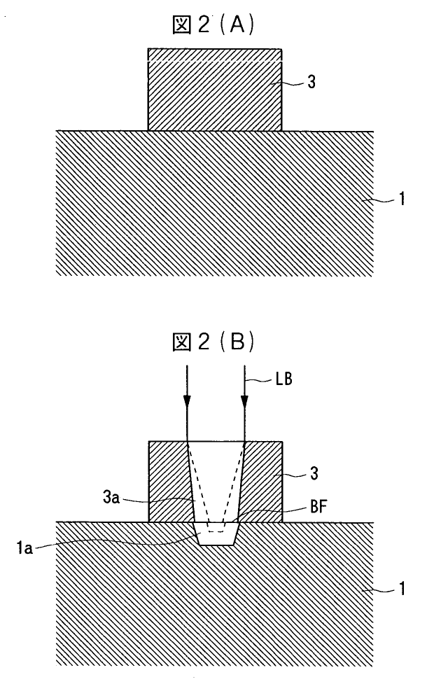

FIGS. 2(A) and 2(B) illustrate a second processing method. The processing method differs from the first processing method in that a light-absorbing layer 3 is provided only at a part to be processed of the surface to be processed of the transparent material 1. In this drawing, reference numeral 3a denotes a part removed when the light-absorbing layer 3 is irradiated with the laser beam LB. According to the processing method, since the light-absorbing layer 3 is provided only at the part to be processed, the material cost of the light-absorbing layer 3 can be advantageously reduced.

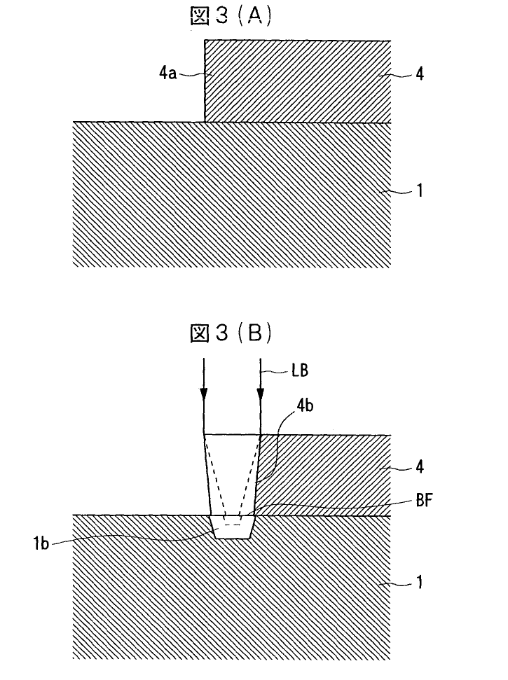

FIGS. 3(A) and 3(B) illustrate a third processing method. The processing method differs from the first processing method in that the laser beam LB is applied along an edge 4a of a light-absorbing layer 4, so that a groove 1b following a contour of the edge 4a is formed in the surface to be processed of the transparent material 1. In this drawing, reference numeral 4b denotes a part removed when the laser beam LB is applied along the edge 4a of the light-absorbing layer 4. According to the processing method, a groove in any desired shape can be advantageously formed in the surface to be processed of the transparent material 1 by taking advantage of the contour of the edge 4a of the light-absorbing layer 4. The light-absorbing layer 4 used in this method may be a partial one provided only at the part to be processed, similar to the light-absorbing layer 3 used in the second processing method.

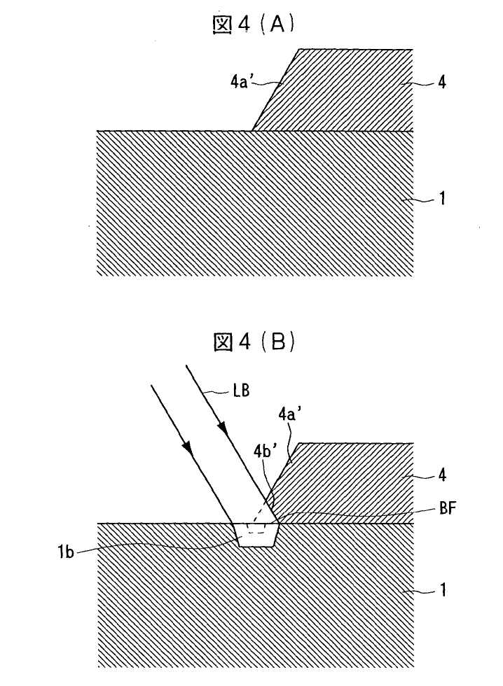

FIGS. 4(A) and 4(B) illustrate a variation of the third processing method. The processing method differs from the third processing method in that the light-absorbing layer 4 has an edge 4a, slanted at an acute angle with respect to the surface to be processed of the transparent material 1, and the laser beam LB is applied along a boundary between the slanted edge 4a′ and the surface to be processed of the transparent material 1, thereby forming a groove 1b following a contour of the boundary in the surface to be processed of the transparent material 1. In this drawing, the axis of the applied laser beam LB is shown as being slanted to form an acute angle with the surface to be processed of the transparent material 1. However, the axis of the applied laser beam LB may be perpendicular to the surface to be processed of the transparent material 1. In this drawing, reference numeral 4b′ denotes a part of the edge 4a′ removed when the laser beam LB is applied along the boundary. According to the processing method, while part of the applied laser beam LB is applied to the light-absorbing layer 4 and the remaining part thereof is applied to the surface to be processed of the transparent material 1, a groove in any desired shape can be precisely formed in the surface to be processed of the transparent material 1 by taking advantage of the contour of the boundary.

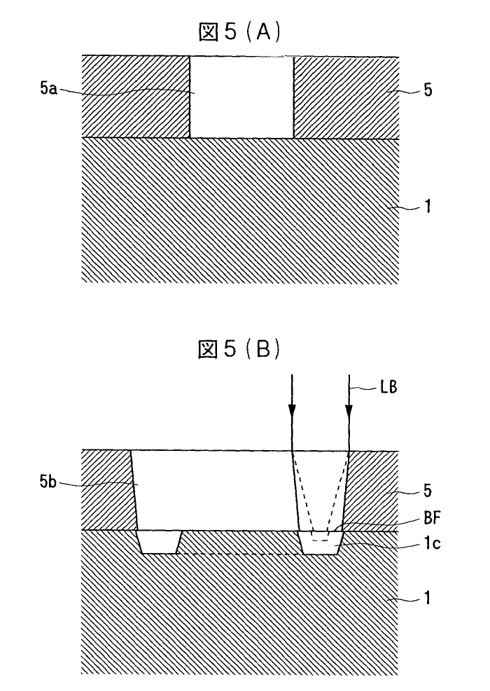

FIGS. 5(A) and 5(B) illustrate a fourth processing method. The processing method differs from the first processing method in that a light-absorbing layer 5 has a through hole 5a, and the laser beam LB is applied along an edge of the through hole 5a in the light-absorbing layer 5, thereby forming an annular groove 1c following a contour of the edge of the through hole in the surface to be processed of the transparent material 1. In this drawing, reference numeral 5b denotes a part removed when the laser beam LB is applied along the edge of the through hole in the light-absorbing layer 5. According to the processing method, an annular or a curved groove in any desired shape can be advantageously precisely formed in the surface to be processed of the transparent material 1 by taking advantage of the contour of the edge of the through hole. The light-absorbing layer 5 used in this method may be a partial one provided only at the part to be processed, similar to the light-absorbing layer 3 used in the second processing method. In addition, if the through hole 5a is shaped into an inverted truncated cone with an inner wall thereof being slanted at an acute angle with respect to the surface to be processed of the transparent material 1, processing can be accomplished in a similar manner to the processing method described with reference to FIGS. 4(A) and 4(B).

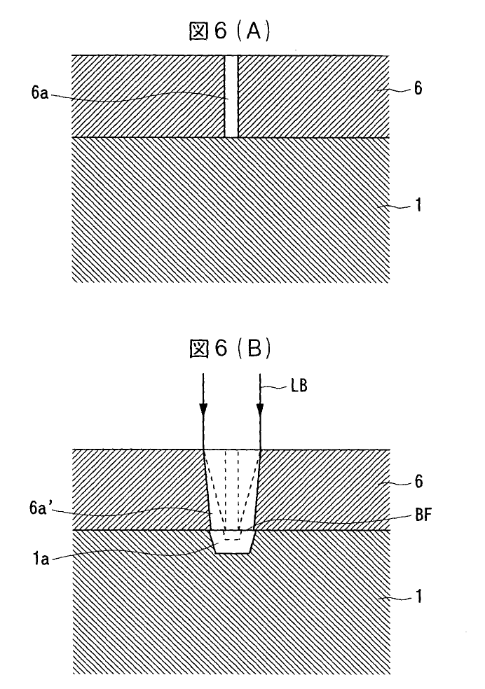

FIGS. 6(A) and 6(B) illustrate a fifth processing method. The processing method differs from the first processing method in that a light-absorbing layer 6 has a through hole 6a having a diameter smaller than a spot of the applied laser beam LB or a through slit having a width smaller than the spot (not shown), and the laser beam LB is applied to the hole 6a or slit in the light-absorbing layer 6, thereby forming a hole 1a or a groove in the surface to be processed of the transparent material 1. In this drawing, reference numeral 6a′ denotes a part of an inner wall of the hole 6a or the slit in the light-absorbing layer 6 which is removed when the laser beam LB is applied thereto. According to the processing method, the hole 1a or the groove can be advantageously precisely formed in the surface to be processed of the transparent material 1 by using the hole 6a or the slit, which is previously formed in the light-absorbing layer 6, as a target. In addition, even if the light-absorbing layer 6 is made of metal which is difficult to perforate, an intended processing can be advantageously accomplished without any problem by removing a part of the inner wall of the hole 6a or the slit with the laser beam LB. The light-absorbing layer 6 used in this method may be a partial one provided only at the part to be processed similar to the light-absorbing layer 3 used in the second processing method, or may have a nozzle-like configuration. Furthermore, the through hole 6a or the slit may be gradually increased in cross section from the lower end to the upper end thereof. For example, it may be an inverted truncated cone, inverted truncated pyramid or inverted triangle in vertical section.

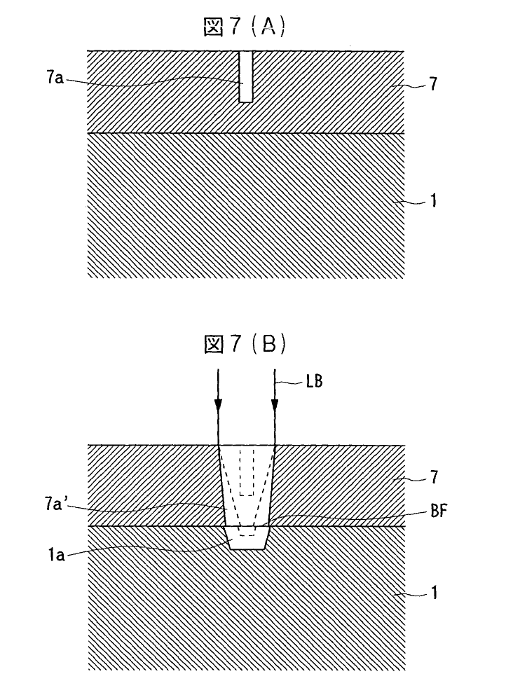

FIGS. 7(A) and 7(B) illustrate a sixth processing method. The process method from the first processing method in that a light-absorbing layer 7 has a non-through hole 7a having a diameter smaller than a spot of the applied laser beam LB or a non-through slit having a width smaller than the spot (not shown), and the laser beam LB is applied to the hole 7a or the slit in the light-absorbing layer 7, thereby forming a hole 1a or a groove in the surface to be processed of the transparent material 1. In this drawing, reference numeral 7a′ denotes a part of an inner wall of the hole 7a or the slit in the light-absorbing layer 7 which is removed when the laser beam LB is applied thereto. According to the processing method, the hole 1a or the groove can be advantageously precisely formed in the surface to be processed of the transparent material 1 by using the hole 7a or slit, which is previously formed in the light-absorbing layer 7, as a target. In addition, even if the light-absorbing layer 7 is made of metal which is difficult to perforate, an intended processing can be advantageously accomplished without any problem by removing a part of the inner wall of the hole 7a or the slit with the laser beam LB. The light-absorbing layer 7 used in this method may be a partial one provided only at the part to be processed similar to the light-absorbing layer 3 used in the second processing method, or may have a nozzle-like configuration. Furthermore, the non-through hole 7a or the non-through slit may be gradually increased in cross section from the lower end to the upper end thereof. For example, it may be an inverted truncated cone, inverted truncated pyramid or inverted triangle in vertical section.

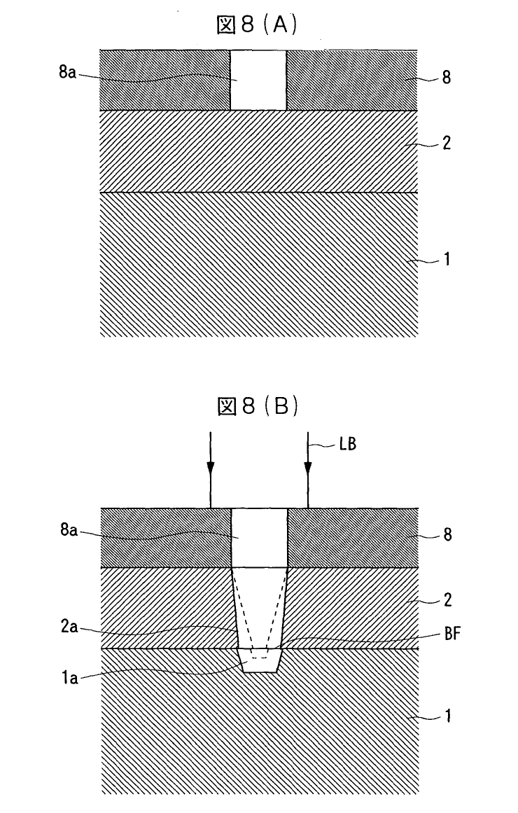

FIGS. 8(A) and 8(B) illustrate a seventh processing method. The processing method differs from the first processing method in that a mask 8 having a transparent region 8a in a predetermined shape smaller than a spot of the applied laser beam LB is provided on the light-absorbing layer 2, and the laser beam LB is applied to the light-absorbing layer 2 through the transparent region 8a of the mask 8. For example, the mask 8 may be made of stainless steel, which reflects the laser beam LB; or may be composed of a metal or plastic plate having a low reflectivity to the laser beam and a reflection film provided thereon. According to the processing method, a hole 1a or a groove in the same shape as the transparent region 8a of the mask 8 can be advantageously formed in the surface to be processed of the transparent material 1. In the processing method described so far, a contact exposure is adopted in which the mask 8 is brought into contact with the light-absorbing layer 2 for exposure, for example. In this case, the mask 8 may be a conformal mask. Alternatively, a projection exposure may be adopted in which the mask 8 is spaced apart from the light-absorbing layer 2 for exposure. In this case, an optical coupling system, such as a projection lens, may be interposed between the mask 8 and the light-absorbing layer 2.

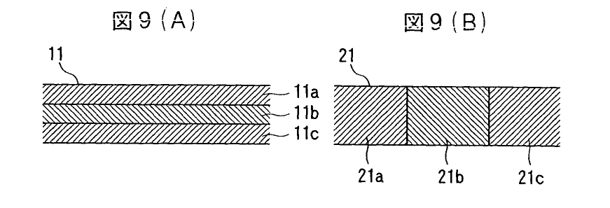

In the processing methods described above, the light-absorbing layers 2-7 are all single-layered. However, a light-absorbing layer comprising a plurality of parts with different extinction coefficients may be used. FIG. 9(A) shows a case where a plurality of parts 11a-11c with different extinction coefficients of a light-absorbing layer 11 are stacked in the thickness direction thereof. FIG. 9(B) shows a case where a plurality of parts 21a-21c with different extinction coefficients of a light-absorbing layer 21 are arranged in a direction perpendicular to the thickness direction thereof.

In the case of the light-absorbing layer 11 shown in FIG. 9(A), the plurality of parts 11a-11c with different extinction coefficients allow stepwise control of the energy of the laser beam LB that reaches the transparent material 1. In particular, if the extinction coefficient of the plurality of parts 11a-11c with different extinction coefficients is decreased stepwise from the light irradiation side to the opposite side, the energy of the laser beam LB that reaches the transparent material 1 can be controlled stepwise to form a hole larger in depth than in diameter or a groove larger in depth than in width.

On the other hand, in the case of the light-absorbing layer 21 shown in FIG. 9(B), various kinds of processing of the transparent material 1 can be accomplished by selectively applying the laser beam LB to the plurality of parts 21a-21c with different extinction coefficients of the light-absorbing layer 21 in a state where the parts 21a-21c are all in contact with the transparent material 1. Alternatively, any processing of the transparent material 1 can be accomplished by selectively bringing the plurality of parts 21a-21c with different extinction coefficients of the light-absorbing layer 21 into contact with the transparent material 1 and applying the laser beam LB to the selected part.

In the processing methods described above, as a method of applying the laser beam LB, the method of applying the pulsed laser beam of the predetermined energy intermittently the plurality of times, and the method of applying the laser beam of a predetermined power continuously for the predetermined time have been illustrated. In the case of applying the pulsed laser beam intermittently the plurality of times, the energy of the pulsed laser beam may be reduced or increased every time the beam is applied. In the case of applying the laser beam continuously for the predetermined time, the power of the laser beam may be gradually reduced or increased with the lapse of time of the application.

Furthermore, in the processing methods described above, the light-absorbing layers 2-7 are each provided in contact with the transparent material 1. However, the light-absorbing layer 2-7 does not necessarily need to be in contact with the surface to be processed of the transparent material 1. Processings similar to those described above can be accomplished even if a microscopic gap of 100 μm or less which allows heat conduction is formed between the light-absorbing layer and the surface to be processed of the transparent material 1.

Examples for which the processing methods described above are applied will be introduced below.

### EXAMPLE 1

A polymethyl methacrylate film was attached to a surface of a quartz glass, and 400 shots of ArF excimer laser beam (γ=193 nm) having an energy of 0.5 J/cm² per shot were applied intermittently with a pulse width of 37 nsec and a repetition frequency of 10 Hz, thereby forming a hole in the surface of the quartz glass. In this case, the penetration depth 1/α of the laser beam was 5 μm, and thus, the polymethyl methacrylate film having a thickness t of 125 μm was used. Then, a hole having a diameter of 1 μm and a depth of 1 μm was formed in the surface of the quartz glass.

For comparison, the same processing method as described above was implemented except that the polymethyl methacrylate film was removed and an ArF excimer laser beam having an energy of 2 J/cm² per shot was applied directly to the quartz glass. Furthermore, the same processing method as described above was implemented except that the polymethyl methacrylate film having a thickness t of 5 μm or less, for example, 1 μm was used and an ArF excimer laser beam having an energy of 2 J/cm² per shot was applied to the quartz glass. In both cases, there was no imprint of processing on the surface of the quartz glass.

### EXAMPLE 2

A polymethyl methacrylate film was attached to a surface of a single crystalline silicon carbide (SiC) substrate, and 400 shots of ArF excimer laser beam (γ=193 nm) having an energy of 1.5 J/cm² per shot were applied intermittently with a pulse width of 37 nsec and a repetition frequency of 10 Hz, thereby forming a hole in the surface of the single crystalline silicon carbide substrate. In this case, the penetration depth 1/α of the laser beam was 5 μm, and thus, the polymethyl methacrylate film having a thickness t of 125 μm was used. Then, a hole having a diameter of 20 μm and a depth of 1 μm was formed in the surface of the single crystalline silicon carbide substrate.

For comparison, the same processing method as described above was implemented except that the polymethyl methacrylate film was removed and an ArF excimer laser beam having an energy of 1.5 J/cm² per shot was applied directly to the single crystalline silicon carbide substrate. Furthermore, the same processing method as described above was implemented except that the polymethyl methacrylate film having a thickness t of 5 μm or less, for example, 1 μm was used and an ArF excimer laser beam having an energy of 1.5 J/cm² per shot was applied to the quartz glass. In both cases, there was no imprint of processing on the surface of the single crystalline silicon carbide substrate.

### EXAMPLE 3

A polyethylene film containing carbon was attached to a surface of a quartz glass, and 500 shots of Q-sw Nd YAG laser beam (γ=1064 nm) having an average power of 0.5 W and a frequency of 1 kHz were applied intermittently with a pulse width of 50 nsec and a repetition frequency of 1 kHz, thereby forming a hole in the surface of the quartz glass. In this case, the penetration depth 1/α of the laser beam was 20 μm, and thus, the polyethylene film having a thickness t of 100 μm was used. Then, a hole having a diameter of 60 μm and a depth of 1 μm was formed in the surface of the quartz glass.

For comparison, the same processing method as described above was implemented except that the polyethylene film was removed and a Q-sw Nd YAG laser beam having an average power of 1 W and a frequency of 1 kHz was applied directly to the quartz glass. Furthermore, the same processing method as described above was implemented except that the polyethylene film having a thickness t of 20 μm or less, for example, 5 μm was used and a Q-sw Nd YAG laser beam having an average power of 1 W and a frequency of 1 kHz was applied to the quartz glass. In both cases, there was no imprint of processing on the surface of the quartz glass.

### EXAMPLE 4

A polyethylene film containing carbon was attached to a surface of a quartz glass, and a CW Nd YAG laser beam (γ=1064 nm) having a power of 2 W was continuously applied for 5 msec, thereby forming a hole in the surface of the quartz glass. In this case, the penetration depth 1/α of the laser beam was 20 μm, and thus, the polyethylene film having a thickness t of 100 μm was used. Then, a hole having a diameter of 60 μm and a depth of 1 μm was formed in the surface of the quartz glass.

For comparison, the same processing method as described above was implemented except that the polyethylene film was removed and a CW Nd YAG laser beam having a power of 5 W was continuously applied for 5 msec. Furthermore, the same processing method as described above was implemented except that the polyethylene film having a thickness t of 20 μm or less, for example, 5 μm was used and a CW Nd YAG laser beam having a power of 5 W was continuously applied for 5 msec to the quartz glass. In both cases, there was no imprint of processing on the surface of the quartz glass.

### EXAMPLE 5

A polyethylene film containing carbon was attached to a surface of a quartz glass, and a semiconductor laser beam (γ=808 nm) having a power of 20 W was continuously applied for 10 msec, thereby forming a hole in the surface of the quartz glass. In this case, the penetration depth 1/α of the laser beam was 25 μm, and thus, the polyethylene film having a thickness t of 100 μm was used. Then, a hole having a diameter of 200 μm and a depth of 2 μm was formed in the surface of the quartz glass.

For comparison, the same processing method as described above was implemented except that the polyethylene film was removed and a semiconductor laser beam having a power of 20 W was continuously applied for 10 msec to the quartz glass. Furthermore, the same processing method as described above was implemented except that the polyethylene film having a thickness t of 25 μm or less, for example, 5 μm was used and a semiconductor laser beam having a power of 20 W was continuously applied for 10 msec to the quartz glass. In both cases, there was no imprint of processing on the surface of the quartz glass.

### EXAMPLE 6

A polymethyl methacrylate film containing a pigment was attached to a surface of a quartz glass, and an operation of applying thereto 100 shots of KrF excimer laser beam (μ=248 nm) having an energy of 0.5 J/cm² per shot intermittently with a pulse width of 37 nsec and a repetition frequency of 100 Hz was repeated by changing stepwise the position to which the laser beam is applied, thereby forming a linear groove in the surface of the quartz glass to provide an optical diffraction element. In this case, the penetration depth 1/α of the laser beam was 2 μm, and thus, the polymethyl methacrylate film having a thickness t of 25 μm was used. Then, a linear groove having a width of 1 μm and a depth of 0.5 tun was formed in the surface of the quartz glass.

For comparison, the same processing method as described above was implemented except that the polymethyl methacrylate film was removed and a KrF excimer laser beam having an energy of 2 J/cm² per shot was applied directly to the quartz glass. Furthermore, the same processing method as described above was implemented except that the polymethyl methacrylate film having a thickness t of 2 μm or less, for example, 0.5 μm was used and a KrF excimer laser beam having an energy of 2 J/cm² per shot was applied to the quartz glass. In both cases, there was no imprint of processing on the surface of the quartz glass.

### EXAMPLE 7

A ceramics sheet containing 65% by weight of SiO₂, 1% by weight of Al₂O₃, 8% by weight of CaO, 13% by weight of Na₂O and 10% by weight of TiO₂ was attached to a surface of a quartz glass, and 200 shots of ArF excimer laser beam (γ=193 nm) having an energy of 2 J/cm² per shot were applied intermittently with a pulse width of 37 nsec and a repetition frequency of 10 Hz, thereby forming a hole in the surface of the quartz glass. In this case, the penetration depth 1/α of the laser beam was 5 μm, and thus, the ceramics sheet having a thickness t of 100 μm was used. Then, a hole having a diameter of 30 μm and a depth of 15 μm was formed in the surface of the quartz glass.

For comparison, the ceramics sheet was removed and the laser beam was applied directly to the quartz glass under the same condition. Then, there was no imprint of processing on the surface of the quartz glass.

### EXAMPLE 8

A dried unbaked ceramics sheet containing 70% by weight of SiO₂, 1% by weight of Al₂O₃, 8% by weight of CaO, 13% by weight of Na₂O, 5% by weight of carbon and 3% by weight of an organic binder was attached to a surface of a quartz glass, and 200 shots of ArF excimer laser beam (γ=193 nm) having an energy of 1.5 J/cm² per shot were applied intermittently with a pulse width of 37 nsec and a repetition frequency of 10 Hz, thereby forming a hole in the surface of the quartz glass. In this case, the penetration depth 1/α of the laser beam was 2 μm, and thus, the ceramics sheet having a thickness t of 100 μm was used. Then, a hole having a diameter of 30 μm and a depth of 10 μm was formed in the surface of the quartz glass.

For comparison, the unbaked ceramics sheet was removed and the laser beam was applied directly to the quartz glass under the same condition. Then, there was no imprint of processing on the surface of the quartz glass.

### EXAMPLE 9

A slurry containing 60% by weight of SiO₂, 25% by weight of an organic binder, 34% by weight of an organic solvent and 1% by weight of a pigment was applied to a surface of a quartz glass, and 200 shots of ArF excimer laser beam (γ=193 nm) having an energy of 1.5 J/cm² per shot were applied intermittently with a pulse width of 37 nsec and a repetition frequency of 10 Hz, thereby forming a hole in the surface of the quartz glass. In this case, the penetration depth 1/α of the laser beam was 5 μm, and thus, the slurry film was deposited to a thickness of 100 μm. Then, a hole having a diameter of 20 μm and a depth of 10 μm was formed in the surface of the quartz glass.

For comparison, the slurry film was removed and the laser beam was applied directly to the quartz glass under the same condition. Then, there was no imprint of processing on the surface of the quartz glass.

### EXAMPLE 10

A Cu thin film was formed on a surface of a quartz glass, and 200 shots of ArF excimer laser beam (γ=193 nm) having an energy of 2 J/cm² per shot were applied intermittently with a pulse width of 37 nsec and a repetition frequency of 10 Hz, thereby forming a hole in the surface of the quartz glass. In this case, the penetration depth 1/α of the laser beam was 1 μm, and thus, the Cu thin film having a thickness t of 20 μm was used. Then, a hole having a diameter of 20 μm and a depth of 5 μm was formed in the surface of the quartz glass.

For comparison, the Cu thin film was removed and the laser beam was applied directly to the quartz glass under the same condition. Then, there was no imprint of processing on the surface of the quartz glass.

### EXAMPLE 11

A carbon paste containing 50% by weight of carbon powder, 20% by weight of an organic binder and 30% by weight of an organic solvent was applied to a surface of a quartz glass, and a CW Nd YAG laser beam (γ=1064 nm) having a power of 2 W was continuously applied for 5 msec, thereby forming a hole in the surface of the quartz glass. In this case, the penetration depth 1/α of the laser beam was 5 μm, and thus, the paste film was deposited to a thickness of 50 μm. Then, a hole having a diameter of 50 μm and a depth of 1 μm was formed in the surface of the quartz glass.

For comparison, the paste film was removed and the laser beam was applied directly to the quartz glass under the same condition. Then, there was no imprint of processing on the surface of the quartz glass.

### EXAMPLE 12

A polymethyl methacrylate film was attached to a surface of a quartz glass, and an operation of applying thereto 400 shots of ArF excimer laser beam (γ=193 nm) having an energy of 0.8 J/cm² per shot intermittently with a pulse width of 37 nsec and a repetition frequency of 10 Hz was repeated by changing the position to which the laser beam is applied stepwise along the edge of the polymethyl methacrylate film, thereby forming a linear groove in the surface of the quartz glass. In this case, the penetration depth 1/α of the laser beam was 5 μm, and thus, the polymethyl methacrylate film having a thickness t of 125 μm was used. Then, a linear groove having a width of 1 μm and a depth of 1 μm was formed in the surface of the quartz glass.

For comparison, the polymethyl methacrylate film was removed and the laser beam was applied directly to the quartz glass under the same condition. Then, there was no imprint of processing on the surface of the quartz glass.

### EXAMPLE 13

A polymethyl methacrylate film having a through hole previously formed was attached to a surface of a quartz glass, and an operation of applying thereto 400 shots of ArF excimer laser beam (γ=193 nm) having an energy of 0.8 J/cm² per shot intermittently with a pulse width of 37 nsec and a repetition frequency of 10 Hz was repeated by changing the position to which the laser beam is applied stepwise along the edge of the through hole in the polymethyl methacrylate film, thereby forming an annular groove in the surface of the quartz glass. In this case, the penetration depth 1/α of the laser beam was 5 μn, and thus, the polymethyl methacrylate film having a thickness t of 125 μm was used. Then, an annular groove having a width of 1 μm and a depth of 0.2 μm was formed in the surface of the quartz glass.

For comparison, the polymethyl methacrylate film was removed and the laser beam was applied directly to the quartz glass under the same condition. Then, there was no imprint of processing on the surface of the quartz glass.

### EXAMPLE 14

A nozzle-like piece made of carbon glass having previously formed a through hole having a diameter smaller than a spot of the applied laser beam LB (see the fifth processing method) was disposed on a surface of a quartz glass, and a CW Nd YAG laser beam (γ=1064 nm) having a power of 5 W was continuously applied to the through hole for 5 msec, thereby forming a hole in the surface of the quartz glass. In this case, the penetration depth 1/α of the laser beam was 5 μm, and thus, the nozzle-like piece made of carbon glass having a thickness t of 125 μm was used. Then, a hole having a diameter of 50 μm and a depth of 10 μm was formed in the surface of the quartz glass.

For comparison, the nozzle-like piece made of carbon glass was removed and the laser beam was applied directly to the quartz glass under the same condition. Then, there was no imprint of processing on the surface of the quartz glass.

### EXAMPLE 15

A polymethyl methacrylate film was attached to a surface of a quartz glass, and an operation of applying thereto 300 shots of ArF excimer laser beam (γ=193 nm) having an energy of 2 J/cm² per shot intermittently with a pulse width of 37 nsec and a repetition frequency of 10 Hz was repeated by changing the position to which the laser beam is applied stepwise along a predetermined path, thereby forming a groove following the path in the surface of the quartz glass to provide an intaglio printing. In this case, the penetration depth 1/α of the laser beam was 5 μm, and thus, the polymethyl methacrylate film having a thickness t of 125 μm was used. Then, a groove for the intaglio printing having a width of 10 μm and a depth of 5 μm was formed in the surface of the quartz glass.

The quartz glass intaglio printing is used for printing a medium, such as paper and a ceramics green sheet, with a fluid, such as an ink and conductive paste. The groove has a cross section in the shape of a trapezoid with an upper side width being longer than a lower side width, and the contour of the finished groove is sharp. Therefore, the fluid filling the groove smoothly comes off the groove during printing, so that the printing can be accomplished with high precision.

For comparison, the polymethyl methacrylate film was removed and the laser beam was applied directly to the quartz glass under the same condition. Then, there was no imprint of processing on the surface of the quartz glass.

### EXAMPLE 16

A polymethyl methacrylate film was attached to a surface of a quartz glass, and a mask made of stainless steel including a circular transparent region having a diameter of 250 μm and a rectangular transparent region having a size of 100 μm×500 μm was attached to a surface of the polymethyl methacrylate film. 400 shots of ArF excimer laser beam (γ=193 nm) having an energy of 1.5 J/cm² per shot were applied intermittently to the circular transparent region with a pulse width of 37 nsec and a repetition frequency of 10 Hz, and an operation of applying 400 shots of the same ArF excimer laser beam to the rectangular region intermittently with a pulse width of 37 nsec and a repetition frequency of 10 Hz was repeated by changing stepwise the position to which the laser beam is applied, thereby forming an opaque region made of crystallized quartz to provide a quartz glass mask. In this case, the penetration depth 1/α of the laser beam was 5 μm, and thus, the polymethyl methacrylate film having a thickness t of 125 μm was used. Then, a circular opaque region shaped the same as the circular transparent region of the mask and a rectangular opaque region shaped the same as the rectangular transparent region were formed.

The quartz glass mask is used as a mask for processing a workpiece by irradiating the workpiece with a laser beam. Since the opaque region is made of crystallized quartz, the transmittance of the opaque region can be 5% or less of that of the transparent region (non-processed part). In addition, the opaque region can be formed with high precision and a sufficient resistance to the applied laser beam can be assured.

For comparison, the same processing method as described above was implemented except that the polymethyl methacrylate film was removed and an ArF excimer laser beam having an energy of 2 J/cm² per shot was applied directly to the quartz glass. Furthermore, the same processing method as described above was implemented except that the polymethyl methacrylate film having a thickness t of 5 μm or less, for example, 1 μm was used and an ArF excimer laser beam having an energy of 2 J/cm² per shot was applied to the quartz glass. In both cases, there was no imprint of processing on the surface of the quartz glass, and any opaque region could not be formed.

In the experiment example 16 described above, the quartz glass mask for laser processing which has the opaque region in the surface thereof has been illustrated. However, a hole or a groove can be formed according to the shape of the transparent region of the mask as described above with reference to the experiment examples 1 to 15 by adjusting the energy of the applied laser beam and extinction coefficient of the light-absorbing layer in the case where a pulsed laser beam having a predetermined energy is applied intermittently a plurality of times; or by adjusting the power of the applied laser beam, the duration of application of the laser beam and the extinction coefficient of the light-absorbing layer in the case where a laser beam having a predetermined power is applied continuously for a predetermined time.

As described above, according the processing method of forming a hole or a groove in the surface to be processed of the transparent material 1 by applying the laser beam LB to the surface through the light-absorbing layer 2-7, the hole, the groove or the like can be formed precisely in the transparent material 1 with a low energy laser the transparent material 1 or the like, by setting the thickness t of the light-absorbing layer 2 at a value more than the penetration depth of the laser beam, the penetration depth being expressed by 1/α where the extinction coefficient of the light-absorbing layer 2 for the laser beam LB is a.

Furthermore, according the processing method of applying the laser beam LB to the light-absorbing layer 2(3-7) through the transparent region 8a of the mask 8, as described above, the transparent material 1 can be processed precisely according to the shape of the transparent region of the mask 8 with a low energy laser beam LB without regard to the kind of the laser beam LB, property of the transparent material 1 or the like, by setting the thickness t of the light-absorbing layer 2 at a value more than the penetration depth of the laser beam, the penetration depth being expressed by 1/α where the extinction coefficient of the light-absorbing layer 2 for the laser beam LB is α.

Furthermore, as for the quartz glass mask provided in the experiment example 16, the opaque region made of crystallized quartz is formed in the surface of the quartz glass. Therefore, a sharp contrast can be attained with the extinction coefficient of the opaque region being 5% or less of that of the transparent region (non-processed part). In addition, the opaque region can be formed with high precision and a sufficient resistance to the applied laser beam can be assured. Of course, the quartz glass mask can be used not only as a mask but also widely as an optical element for controlling transmission of a laser beam.

1. A method for processing a transparent material with a laser beam, in which the laser beam is applied through a light-absorbing layer to a surface to be processed of the transparent material to form a hole or a groove in the surface to be processed, wherein
the light-absorbing layer has an edge, and the hole or the groove is formed in the surface to be processed by applying the laser beam along the edge of the light-absorbing layer.

2. The method for processing a transparent material with a laser beam according to claim 1, wherein
the edge of the light-absorbing layer is a slanted face.

3. The method for processing a transparent material with a laser beam according to claim 1 or 2, wherein
the edge is provided at an end of the light-absorbing layer.

4. The method for processing a transparent material with a laser beam according to claim 1 or 2, wherein
the edge is an edge of a hole or a slit formed in the light-absorbing layer.

5. A method for processing a transparent material with a laser beam, in which the laser beam is applied through a light-absorbing layer to a surface to be processed of the transparent material to form a hole or a groove in the surface to be processed, wherein
a thickness of the light-absorbing layer is more than a penetration depth of the laser beam, which is expressed by 1/α, providing that an extinction coefficient of the light-absorbing layer for the laser beam is α.

6. The method for processing a transparent material with a laser beam according to claim 5, wherein
the extinction coefficient a is defined by a formula of ∂I/∂x=−αI (where I is a light intensity and x is a distance).

7. The method for processing a transparent material with a laser beam according to any one of claims 1 to 6, wherein
the light-absorbing layer is provided only at a part to be processed of the surface to be processed of the transparent material.

8. The method for processing a transparent material with a laser beam according to any one of claims 1 to 7, wherein
the light-absorbing layer is provided in contact with the surface to be processed of the transparent material.

9. The method for processing a transparent material with a laser beam according to any one of claims 1 to 7, wherein
the light-absorbing layer is provided with a microscopic gap which allows heat conduction being formed between the light-absorbing layer and the surface to be processed of the transparent material.

10. The method for processing a transparent material with a laser beam according to any one of claims 1 to 9, wherein
the laser beam is applied to the light-absorbing layer in such a manner that a pulsed laser beam having a predetermined energy is applied intermittently a plurality of times.

11. The method for processing a transparent material with a laser beam according to claim 10, wherein
the energy of the pulsed laser beam is reduced every time the beam is applied.

12. The method for processing a transparent material with a laser beam according to claim 10, wherein
the energy of the pulsed laser beam is increased every time the beam is applied.

13. The method for processing a transparent material with a laser beam according to any one of claims 1 to 9, wherein
the laser beam is applied to the light-absorbing layer in such a manner that a laser beam having a predetermined power is applied continuously for a predetermined time.

14. The method for processing a transparent material with a laser beam according to claim 13, wherein
the power of the laser beam is gradually reduced with the lapse of time of the application.

15. The method for processing a transparent material with a laser beam according to claim 13, wherein
the power of the laser beam is gradually increased with the lapse of time of the application.

16. The method for processing a transparent material with a laser beam according to any one of claims 1 to 15, wherein
a mask having a transparent region smaller than a spot of the applied laser beam is used, and the laser beam is applied to the light-absorbing layer though the transparent region of the mask.

17. The method for processing a transparent material with a laser beam according to claim 16, wherein
a contact exposure is adopted as a method of applying the laser beam to the light-absorbing layer through the mask.

18. The method for processing a transparent material with a laser beam according to claim 17, wherein
the mask is a conformal mask.

19. The method for processing a transparent material with a laser beam according to claim 16, wherein
a projection exposure is adopted as a method of applying the laser beam to the light-absorbing layer through the mask.

20. The method for processing a transparent material with a laser beam according to claim 19, wherein
an optical coupling system is interposed between the mask and the light-absorbing layer.

21. The method for processing a transparent material with a laser beam according to any one of claims 1 to 20, wherein
the light-absorbing layer is made of plastic.

22. The method for processing a transparent material with a laser beam according to claim 21, wherein
the plastic is one of polymethyl methacrylate, polyethylene and polyimide.

23. The method for processing a transparent material with a laser beam according to any one of claims 1 to 20, wherein
the light-absorbing layer is made of ceramics.

24. The method for processing a transparent material with a laser beam according to claim 23, wherein
the ceramics contains at least one selected among from SiO₂, Al₂O₃, CaO, Na₂O, B₂O₃, SiC, Si₃N₄, B₄C, TiO₂, BeO, AlN, MgO, BaTiO₃, SrTiO₃, ZnO, SnO₂, CrO₂ and Fe₂O₃.

25. The method for processing a transparent material with a laser beam according to any one of claims 1 to 20, wherein
the light-absorbing layer is a layer of a slurry containing a powdered ceramics or a layer obtained by drying the layer.

26. The method for processing a transparent material with a laser beam according to claim 25, wherein
the slurry contains at least one selected among from powdered ceramics including SiO₂, Al₂O₃, CaO, Na₂O, B₂O₃, SiC, Si₃N₄, B₄C, TiO₂, BeO, AlN, MgO, BaTiO₃, SrTiO₃, ZnO, SnO₂, CrO₂ and Fe₂O₃.

27. The method for processing a transparent material with a laser beam according to any one of claims 1 to 20, wherein
the light-absorbing layer is made of metal.

28. The method for processing a transparent material with a laser beam according to claim 27, wherein
the metal contains at least one selected among from Au, Ag, Pt, Pd, Ni, Cu, Fe and Al.

29. The method for processing a transparent material with a laser beam according to any one of claims 1 to 20, wherein
the light-absorbing layer is a layer of a paste containing a powdered metal or a layer obtained by drying the layer.

30. The method for processing a transparent material with a laser beam according to claim 29, wherein
the paste contains at least one powdered metal selected among from Au, Ag, Pt, Pd, Ni, Cu, Fe and Al.

31. The method for processing a transparent material with a laser beam according to any one of claims 1 to 20, wherein
the light-absorbing layer is made of carbon.

32. The method for processing a transparent material with a laser beam according to any one of claims 1 to 20, wherein
the light-absorbing layer is a layer of a paste containing a powdered carbon or a layer obtained by drying the layer.

33. The method for processing a transparent material with a laser beam according to any one of claims 1 to 32, wherein
the light-absorbing layer contains an extinction coefficient regulator for regulating the extinction coefficient.

34. The method for processing a transparent material with a laser beam according to claim 33, wherein
the extinction coefficient regulator comprises at least one of a pigment, a powdered metal and a powdered carbon.

35. The method for processing a transparent material with a laser beam according to any one of claims 1 to 34, wherein
the light-absorbing layer comprises a plurality of parts with different extinction coefficients.

36. The method for processing a transparent material with a laser beam according to claim 35, wherein
the plurality of parts with different extinction coefficients are stacked in a thickness direction of the light-absorbing layer.

37. The method for processing a transparent material with a laser beam according to claim 36, wherein
each of the plurality of parts with different extinction coefficients is layered, and the plurality of parts are stacked so that the extinction coefficient is decreased stepwise from a light irradiation side to an opposite side.

38. The method for processing a transparent material with a laser beam according to claim 35, wherein
the plurality of parts with different extinction coefficients are arranged in a direction perpendicular to the thickness direction of the light-absorbing layer.

39. The method for processing a transparent material with a laser beam according to claim 38, wherein
in a state where the plurality of parts with different extinction coefficients of the light-absorbing layer are all in contact with the transparent material, the laser beam is applied to each part to process the transparent material.

40. The method for processing a transparent material with a laser beam according to claim 38, wherein
the plurality of parts with different extinction coefficients of the light-absorbing layer are selectively used, and the laser beam is applied to a selected part to process the transparent material.

41. The method for processing a transparent material with a laser beam according to any one of claims 1 to 40, wherein
the laser beam is any one of a gas laser beam, a solid state laser beam and a semiconductor laser beam.

42. A product obtained by processing a transparent material by applying a laser beam to a surface to be processed of the transparent material through a light-absorbing layer, wherein
an extinction coefficient of a processed part is 5% or less of that of a non-processed part.

43. The product obtained by processing a transparent material according to claim 42, wherein
the transparent material is a quartz glass.

44. The product obtained by processing a transparent material according to claim 43, wherein
the processed part contains a crystallized quartz.

45. The product obtained by processing a transparent material according to any one of claims 42 to 44, wherein
the product is used as a mask for processing a workpiece by applying a laser beam to the workpiece.
